(19) United States
(12) Patent Application Publication
(10) Pub. No.: US 2016/0033881 A1
(43) Pub. Date: Feb. 4, 2016

(54) DUAL STAGE/DUAL CHUCK FOR MASKLESS LITHOGRAPHY

(71) Applicant: Applied Materials, Inc., Santa Clara, CA (US)

(72) Inventor: Christopher Dennis BENCHER, Cupertino, CA (US)

(21) Appl. No.: 14/802,908

(22) Filed: Jul. 17, 2015

Related U.S. Application Data
(60) Provisional application No. 62/094,043, filed on Dec. 18, 2014.
(60) Provisional application No. 62/032,489, filed on Aug. 1, 2014.

(51) Int. Cl. G03F 7/20

(52) U.S. Cl. CPC G03F 7/70725

(57) ABSTRACT

A processing system including at least processing apparatus and at least two independently moveable stages is disclosed. The at least two independently moveable stages are movable between a processing position and at a respective loading position. The at least one processing apparatus may include a maskless pattern generator. The processing system includes a controller configured to instruct the movement of the independently moveable stages in order to minimize the idle time of the processing apparatus. Methods of using the processing system are also disclosed.

### CROSS-REFERENCE TO RELATED APPLICATIONS

This application claims benefit of U.S. Provisional Patent Application Ser. No. 62/032,489 (APPM/21889L), filed Aug. 1, 2014, and U.S. Provisional Patent Application Ser. No. 62/094,043 (APPM/21889L02), filed Dec. 18, 2014, both of which are herein incorporated by reference.

### BACKGROUND

1. Field

The present disclosure generally relates to methods and apparatuses for processing one or more substrates, and more specifically to methods and apparatuses for performing photolithography processes.

2. Description of the Related Art

Photolithography is widely used in the manufacturing of semiconductor devices and display devices, such as liquid crystal displays (LCDs). Large area substrates are often utilized in the manufacture of LCDs. LCDs, or flat panels, are commonly used for active matrix displays, such as computers, touch panel devices, personal digital assistants (PDAs), cell phones, television monitors, and the like. Generally, flat panels may comprise a layer of liquid crystal material forming pixels sandwiched between two plates. When power from the power supply is applied across the liquid crystal material, an amount of light passing through the liquid crystal material may be controlled at pixel locations enabling images to be generated.

Microlithography techniques are generally employed to create electrical features incorporated as part of the liquid crystal material layer forming the pixels. According to this technique, a light-sensitive photoresist is typically applied to at least one surface of the substrate. Then, either a photolithography mask or pattern generator exposes selected areas of the light-sensitive photoresist as part of a pattern with light to cause chemical changes to the photoresist in the selective areas to prepare these selective areas for subsequent material removal and/or material addition processes to create the electrical features.

In order to continue to provide display devices and other devices to consumers at the prices demanded by consumers, device manufacturers must increase manufacturing throughput. Therefore, new apparatuses and approaches are needed to precisely and cost-effectively create patterns on substrates, such as large area substrates.

### SUMMARY

Embodiments disclosed herein increase device throughput by decreasing the idle time of a processing apparatus of a processing system by performing the positioning and alignment of a substrate to be processed while simultaneously processing another substrate.

Embodiments disclosed herein include a processing system. The processing system includes at least one processing apparatus. The processing system also includes at least two stages. Each stage is independently moveable between a processing position and a respective loading position. At least one processing position is located between at least two loading positions. Each stage is also configured to align a substrate positioned thereon. The number of independently moveable stages is greater than the number of processing apparatuses. The processing system also includes a controller. The controller is configured to instruct the movement of a first stage positioned at a processing position. The controller is configured to provide the movement instruction in response to the completion of a substrate processing procedure performed at the processing position by the at least one processing apparatus. The controller is also configured to instruct the movement of a second stage positioned at the loading position. The controller is configured to provide the movement instruction in response to the completion of a substrate alignment procedure performed at the respective loading position.

Embodiments disclosed herein include a method of processing two or more substrates. The method includes processing a first substrate positioned on a first independently moveable stage at a processing position for a first predetermined period of time. The method also includes aligning a second substrate positioned on a second independently moveable stage at a second loading position during the first predetermined period of time. The method further includes moving, after the first predetermined period of time, the second stage to the processing position while moving the first stage toward a first loading position.

Embodiments disclosed herein include a processing system. The processing system includes a single processing apparatus. The processing apparatus is a pattern generator configured to expose a photoresist in a maskless photolithography process. The processing system also includes at least two stages. Each stage is independently moveable between a processing position and a respective loading position. At least one processing position is located between at least two loading positions. Each stage is associated with a single loading position. Each stage is configured to align a substrate positioned thereon. At least one stage includes one or more lift pins. The processing system includes at least one transfer robot configured to position a substrate on at least one of the at least two stages. The processing system also includes a controller. The controller is configured to instruct the movement of a stage positioned at a processing position in response to the completion of a substrate processing procedure performed by the at least one processing apparatus. The controller is configured to instruct the movement of a stage positioned at a loading position in response to the completion of a substrate alignment procedure performed at the respective loading position. The processing system is a linear processing system.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a sectional perspective view of one embodiment of a processing system that may benefit from embodiments disclosed herein.

FIG. 2 is a top perspective view of one embodiment of a stage of the processing system of FIG. 1.

FIG. 3 is a top perspective schematic view of one embodiment of a processing apparatus of the processing system of FIG. 1.

FIG. 4 is a flowchart diagram of one embodiment of a method of processing two or more substrates, according to embodiments disclosed herein.

FIGS. 5A-5D are schematic views of the processing system of FIG. 1 during various stages of one embodiment of the method depicted in FIG. 4.

To facilitate understanding, identical reference numerals have been used, wherever possible, to designate identical elements that are common to the Figures. Additionally, elements of one embodiment may be advantageously adapted for utilization in other embodiments described herein.

### DETAILED DESCRIPTION

Embodiments disclosed herein increase device throughput by decreasing the idle time of a processing apparatus of a processing system by performing the positioning and alignment of a substrate to be processed while simultaneously processing another substrate. For example, embodiments disclosed herein allow for the processing apparatus to be substantially continuously in use during processing, thus increasing throughput.

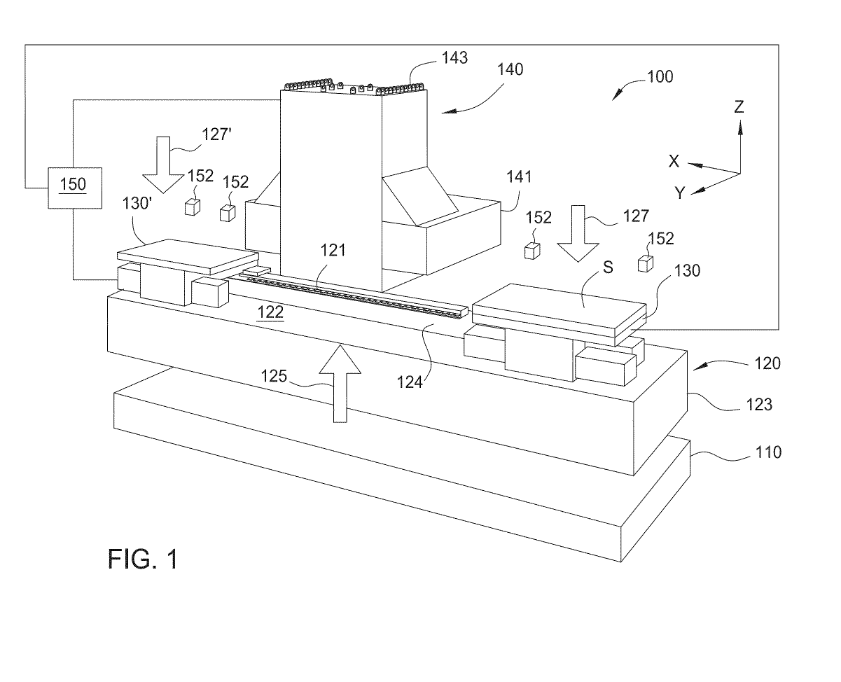

FIG. 1 is a sectional perspective view of one embodiment of a processing system 100 that may benefit from embodiments disclosed herein. As shown, the processing system 100 includes a base frame 110, a track 120, at least one stage 130, a processing apparatus 140, and a controller 150. The base frame 110 may rest on the floor of a fabrication facility and may support the track 120. In some embodiments, passive air isolators (not shown) may be positioned between the base frame 110 and the track 120.

As shown, the track 120 includes a slab 123 and a pair of parallel channels 121 (only one channel 121 is shown in this sectional view). The slab 123 may be comprised of, for example, granite. As shown, the slab 123 has a center surface 122 and a pair of raised portions 124 (only one raised portion 124 is shown in this sectional view). The channels 121 may be positioned above the raised portions 124.

The track 120 includes a pair of loading positions 127, 127′. A transfer robot (not shown) may load or unload a substrate S onto a stage 130 and a stage 130′ at the loading positions 127, 127′, respectively. As shown, the stage 130 has a substrate S positioned thereon. The track 120 also includes a processing position 125. In operation, the stage 130, 130′ may move a substrate S positioned thereon between the processing position 125 and the loading position 127, 127′, respectively. As shown, the loading positions 127, 127′ are opposite each other, and each loading position 127, 127′ is opposite the processing position 125.

While in the respective loading positions 127, 127′, the substrate may be aligned. Observations cameras 152 are disposed over the loading positions 127, 127′. It is to be understood that while only 2 observation cameras 152 have been shown for each loading position 127, 127′, more observation cameras may be present. For example, in one embodiment, 100 cameras may be present for each loading position 127, 127′ arranged in a matrix. In another embodiment, between 2 and 100 observation cameras 152 may be present and arranged in a matrix. The observations cameras 152 are used to view the substrate at multiple locations. The information gathered by the observation cameras 152 is then used to calculate the location of the substrate.

As shown, the track 120 is linear. In other embodiments, the track 120 may have another shape. For example, the track 120 may be “T” shaped or “X” shaped. Also as shown, the processing system includes a single track 120. In other embodiments, the processing system 100 may include more than one track 120. In some embodiments, where the processing system 100 includes more than one track 120, some or all of the tracks 120 may be oriented parallel to each other. In embodiments including parallel tracks 120, a transfer robot may be positioned between two parallel tracks 120. In other embodiments including more than one track 120, some or all of the tracks 120 may have an orientation other than a parallel orientation to each other.

As shown, the processing system 100 includes two stages. In other embodiments, the processing system 100 may include more than two stages. For example, in an embodiment including a T-shaped track 120, the processing system 100 may include three stages. In such an embodiment, each stage may have a loading position at one end of the “T.” In another embodiment including an X-shaped track, the processing system 100 may include four stages. In such an embodiment, the processing system 100 may have a loading position at each end of the “X.” In some embodiments, the number of stages 130 is greater than the number of processing apparatuses 140. In some embodiments, each stage 130 is associated with a single loading position.

The stage 130, 130′ is configured to support a substrate S thereon as the stage 130, 130′ moves along the track 120. In some embodiments, the stage 130, 130′ may be equipped with a system configured to precisely control the movement of the stage 130, 130′ along the track 120. For example, in one embodiment, the stage 130, 130′ is equipped with an air bearing system. In other embodiments, the track 120 and stage 130, 130′ may include a conveyor system.

As shown, the processing apparatus 140 includes a substrate processing unit 143 and a support 141. The processing apparatus is configured to change the chemical or mechanical properties of at least one layer of a substrate S. The support 141 maintains the processing unit 143 above the processing position 125. In one embodiment, the processing unit 143 is a pattern generator configured to expose a photoresist in a photolithography process. In some embodiments, the pattern generator may be configured to perform a maskless lithography process. In other embodiments, the pattern generator may use a mask in a lithography process. In still other embodiments, the processing unit 143 may be another apparatus. As shown, the processing system 100 includes a single processing apparatus 140. In other embodiments, the processing system 100 may include more than one processing apparatus 140.

The processing system 100 also includes a controller 150. The controller 150 is generally designed to facilitate the control and automation of the processing techniques described herein. The controller 150 may be coupled to or in communication with one or more of the processing apparatus 140, the stage 130, and the stage 130′. The processing apparatus 140 and the stage 130, 130′ may provide information to the controller 150 regarding the substrate processing and the substrate aligning. For example, the processing apparatus 140 may provide information to the controller 150 to alert the controller 150 that substrate processing has been completed. In another example, the stage 130, 130′, by use of the observation cameras 152, may provide information to the controller 150 to alert the controller 150 that substrate alignment has been completed. In response to the provided information, the controller 150 may instruct the stage 130, 130′ (or one or more other stages in embodiments including more than two stages) to move along the track, as discussed below.

The controller 150 may include a central processing unit (CPU) (not shown), memory (not shown), and support circuits (or I/O) (not shown). The CPU may be one of any form of computer processors that are used in industrial settings for controlling various processes and hardware (e.g., pattern generators, motors, and other hardware) and monitor the processes (e.g., processing time and substrate position). The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include conventional cache, power supplies, clock circuits, input/output circuitry, subsystems, and the like. A program (or computer instructions) readable by the controller determines which tasks are performable on a substrate. The program may be software readable by the controller 150 and may include code to monitor and control, for example, the processing time and substrate position.

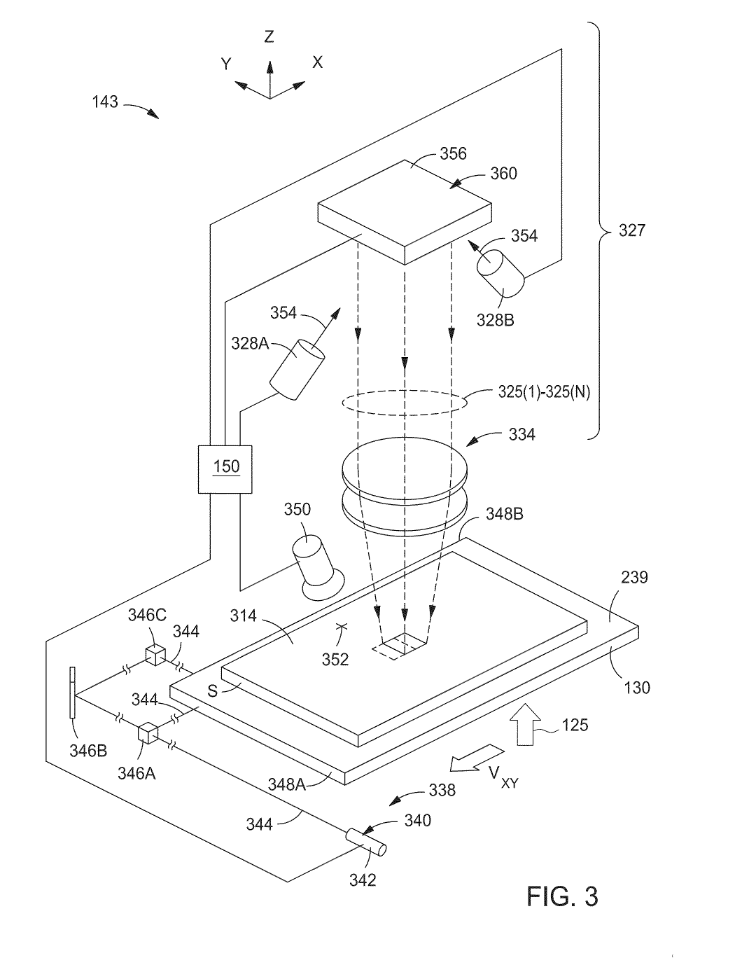

The substrate S may, for example, comprise quartz and be used as part of a flat panel display. In other embodiments, the substrate S may be comprised of other materials. In some embodiments, the substrate S may have a photoresist 314 (shown in FIG. 3) formed thereon. A photoresist is sensitive to radiation and may be a positive photoresist or a negative photoresist, meaning that portions of the photoresist exposed to radiation will be respectively soluble or insoluble to photoresist developer applied to the photoresist after the pattern is written into the photoresist. The chemical composition of the photoresist determines whether the photoresist will be a positive photoresist or negative photoresist. For example, the photoresist may include at least one of diazonaphthoquinone, a phenol formaldehyde resin, poly(methyl methacrylate), poly(methyl glutarimide), and SU-8. In this manner, the pattern may be created on a surface of the substrate S to form the electronic circuitry.

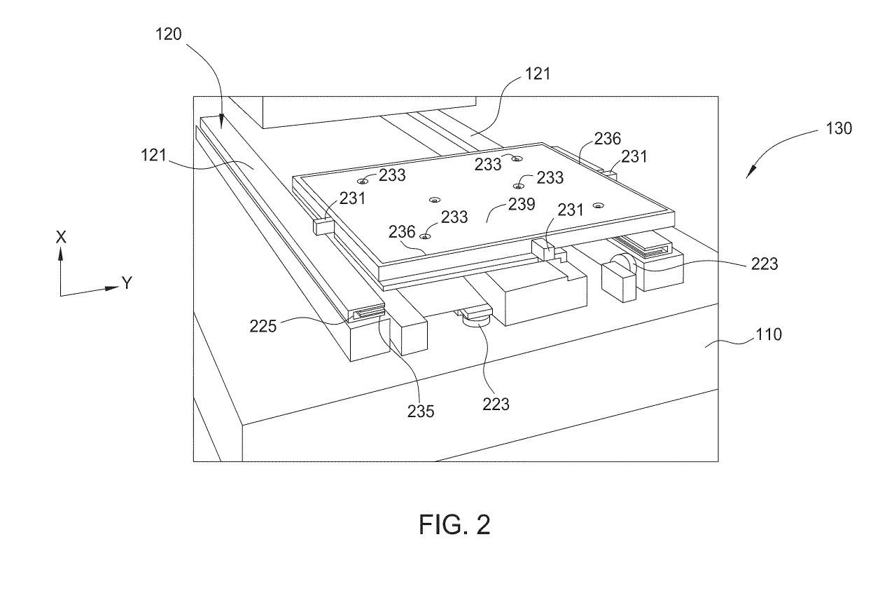

FIG. 2 is a top perspective view of one embodiment of the stage 130 of the embodiment of the processing system 100 depicted in FIG. 1. The stage 130 and the stage 130′ (shown in FIG. 1) may be substantially similar or identical. The stage 130 is configured to receive, align, and transport a substrate S (not shown in this view) along the track 120. The stage 130 has a substrate receiving surface 239 configured to support the substrate S. The stage 130 may have one or more lift pins 233, shown in the unextended position in this view, embedded in the substrate receiving surface 239. The lift pins 233 may rise to an extended position to receive a substrate S, such as from a transfer robot (not shown). The transfer robot may position the substrate S on the lift pins 233, and the lift pins 233 may thereafter gently lower the substrate S onto the substrate receiving surface 239 of the stage 130.

The stage 130 may also include a rim 236. The rim 236 may have an inner diameter sized to accommodate and support a substrate S positioned on the substrate receiving surface 239. The inner portion of the rim 236 may assist in positioning and aligning the substrate S. The inner portion of the rim 236 may also provide lateral support to the substrate S as the stage 130 moves along the track 120.

As shown, the stage 130 includes air bearings 223. The air bearings 223 may assist in receiving the substrate S from the transfer robot by adjusting the position of the stage 130 relative to the substrate S and/or the transfer robot. The air bearings 223 may also move the stage 130 along the track 120.

The stage 130 may also include a projection 235 configured to be received by a recess 225 within at least one channel 121 of the track 120. In some embodiments, the projection 235 may include an electromagnet. The electromagnet may center the stage 130 between the channels 121 of the track 120.

The stage 130 may also include one or more substrate clamps 231. The substrate clamps 231 may secure a substrate S positioned on the stage 130. For example, the substrate clamps 231 may secure the substrate S while the stage 130 moves along the track 120.

FIG. 3 is a top perspective schematic view of a representative embodiment of a processing unit 143 of the processing system of FIG. 1. As shown, the processing unit 143 is a multi-beam pattern generator. The processing unit 143 is configured to write a pattern with a plurality of writing beams 325(1)-325(N) in a photoresist 314 attached to the substrate S. As shown, the stage 130 is in a processing position 125 below a writing mechanism 327. The writing mechanism 327 may include at least one light source 328A, 328B, a writing beam actuator 360, the controller 150, and an optical device 334. The processing unit 143 is depicted as having only a single writing mechanism 327. In other embodiments, the processing unit 143 may include an array of writing mechanisms 327. The array of writing mechanisms 327 may be configured to expose the entire, substantially the entire, or a portion of the surface of the substrate S.

The stage 130 may support the substrate S and move the substrate S relative to the writing beam actuator 360. The stage 130 may include the substrate receiving surface 239 to support the substrate S in the z-direction. The stage 130 may move with the velocity V_{XY} in the x-direction and/or the y-direction to move the substrate S relative to the writing beam actuator 360 so that portions of a pattern may be written by the writing beams 325(1)-325(N) during at least one writing cycle.

The stage 130 also may include a location device 338 to determine a location of the stage 130 and the substrate S during writing. The location device 338 may comprise an interferometer 340, including a laser 342 to emit a laser beam 344 directed by optical components 346A, 346B, 346C to adjacent sides 348A, 348B of the stage 130. Data from the location device 338 may be provided to the controller 150 regarding changes in the position of the stage 130 in the x-direction and/or y-direction.

To ensure that the location of the substrate S may be established relative to the stage 130, the location device 338 also may include an alignment camera 350. The alignment camera 350 may include an optical sensor, for example, a charge coupling device, to read at least one alignment mark 352 on the substrate S to register the substrate S to the stage 130 and the writing beam actuator 360.

As shown, processing unit 143 includes the light source 328A, 328B. The light source 328A, 328B may comprise at least one laser which emits light 354 towards the writing beam actuator 360. The light source 328A, 328B may be configured to emit the light 354 with wavelengths consistent with the use of the photoresist 314. The writing beam actuator 360 may be supplied with radiation energy to be directed as the writing beams 325(1)-325(N) to writing pixel locations on the photoresist 314.

In one embodiment, the writing beam actuator 360 may be a spatial light modulator 356 (SLM). The SLM 356 may comprise mirrors which are individually controlled by signals from the controller 150. The SLM 356 may be, for example, a DLP9500-type digital mirror device made by Texas Instruments Incorporated of Dallas, Texas. The SLM 356 may have the plurality of mirrors, arranged, for example, in 1920 columns and 1080 rows. In this manner, the light 354 may be deflected by the mirrors to the photoresist 314. The controller 150 may instruct the mirrors to be in an active position or an inactive position each writing cycle. The controller 150 also may determine the dose of electromagnetic energy for each writing pixel location.

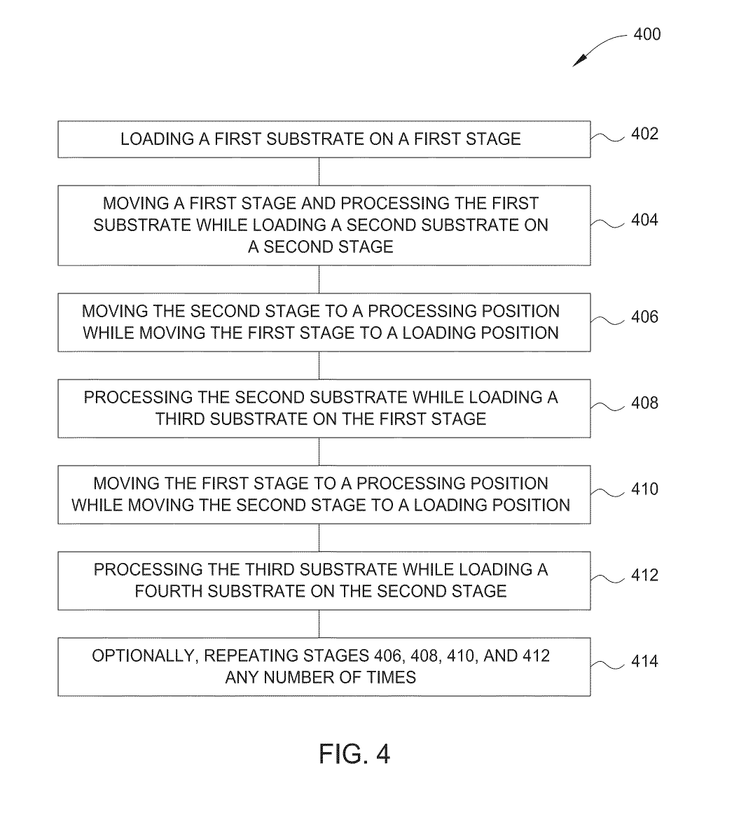

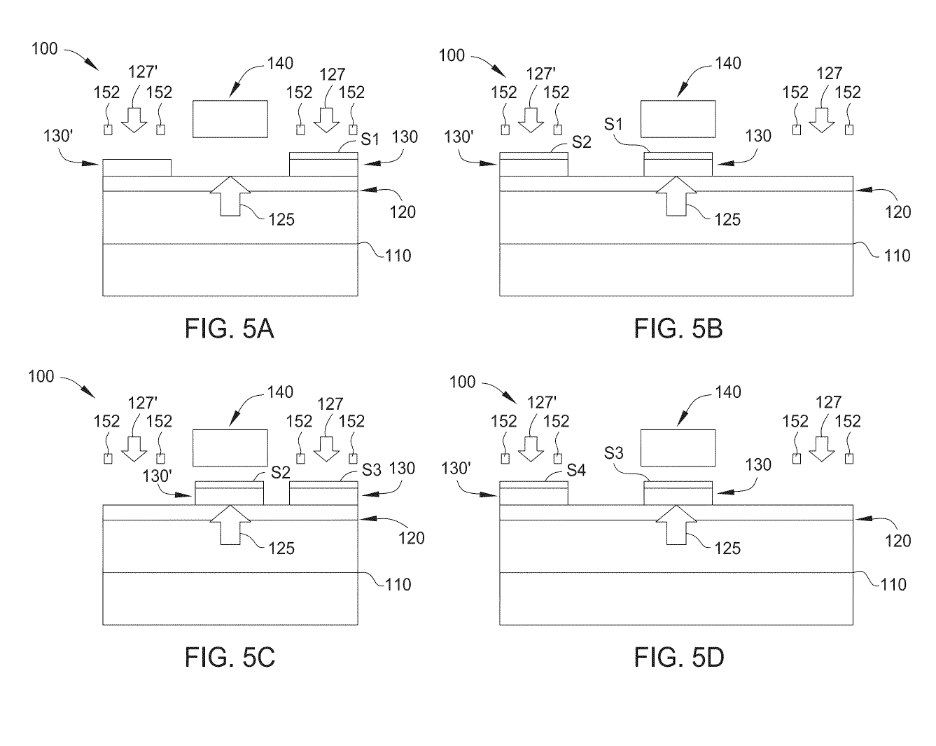

FIG. 4 is a flowchart diagram of one embodiment of a method of processing two or more substrates, according to embodiments disclosed herein. The method for processing the substrate S has multiple stages. The stages can be carried out in any order or simultaneously (except where the context excludes that possibility), and the method can include one or more other stages which are carried out before any of the defined stages, between two of the defined stages, or after all the defined stages (except where the context excludes that possibility). Not all embodiments include all the stages. FIGS. 5A-5D are schematic views of the processing system of FIG. 1 during various stages of one embodiment of the method depicted in FIG. 4.

At stage 402, a first substrate 51 is loaded, positioned, and aligned on a first stage at the loading position 127. The substrate 51 may be as described above. The alignment involves placing the substrate 51 onto the first stage in an approximately aligned orientation. The, the observation cameras 152 view the substrate at multiple locations. The observation cameras 152 view alignment marks that are present on the substrate 51 from the previous processing steps. The exact substrate position is then calculated. The correlation data gathered for the substrate alignment is saved to memory. The first stage may be, for example, the stage 130 described above. The substrate S1 may be loaded and positioned on the stage 130, for example, by a transfer robot. The stage 130 may be configured to align the substrate S1 as described above. In one embodiment, the loading and alignment may take less than about 10 seconds. After stage 402, the processing system 100 may be as depicted in FIG. 5A. In yet another embodiment, the observation cameras 152 view multiple alignment marks across the surface of the substrate S1. The observation cameras 152 infer the relative X,Y substrate versus X,Y stage location, but also infers the substrate distortion such that the X,Y substrate versus the X,Y stage is more than a simple correlation or linear relationship. The observation cameras 152 are configured to view alignment marks disposed on the substrate being processed or view alignment marks disposed on the stage. The alignment data collected by the observation cameras 152 is fed back to the controller that coordinates movement of the stage to align the substrate. Additionally, each observation camera 152 detects the distortion of the substrate such that the coordinates of the substrate and stage is a non-linear relationship

At stage 404, a second substrate S2 is loaded, positioned, and aligned on a second stage at the loading position 127′. The second stage may be, for example, the stage 130′ described above. The substrate S2 may be as described above. The substrate S2 may be loaded and positioned by, for example, a transfer robot. The substrate S2 may be aligned as described above with regards to substrate S1. In one embodiment, the loading and alignment may take less than about 10 seconds.

Also at stage 404, the stage 130 and the substrate S1 may move along a track, such as the track 120, toward a processing position 125 adjacent to a processing apparatus 140. The stage 130 may begin movement in response to an instruction provided by the controller 150. The instruction may be in response to information provided by the stage 130 to the controller 150 informing the controller 150 that the alignment of the substrate S1 has been completed. In one embodiment, the processing apparatus 140 is as described above. Other embodiments may include a different processing apparatus 140. The processing apparatus 140 may process the substrate S1 at the processing position 125 for a first processing time. In one embodiment, the substrate S1 may be processed as described above.

The stage 130 and the substrate S1 may begin moving toward the processing position before or after the substrate S2 is loaded on the stage 130′. In one embodiment, the stage 130 may begin moving toward the processing position 125 within 1 second of the completion of aligning of the substrate S1. After stage 404, the processing system 100 may be as depicted in FIG. 5B.

At stage 406, the stage 130′ moves along the track 120 toward the processing position 125 while the stage 130 moves along the track toward the loading position 127. The movement of the stages 130, 130′ may be in response to an instruction provided by the controller 150. The instruction to move the stage 130 may be in response to information provided to the controller 150 that the processing of the substrate S1 has been completed or a determination made by the controller 150 that the processing of the substrate S1 has been completed. The controller 150 may determine that processing has been completed based on the expiry of a predetermined amount of time or otherwise. The instruction to move the stage 130′ may be in response to information provided to the controller 150 that the processing of the substrate S1 has been completed or a determination made by the controller 150 that the processing of the substrate S1 has been completed. The instruction to move the stage 130′ may be in response to information provided to the controller 150 that the alignment of the substrate S2 has been completed or a determination made by the controller 150 that the alignment of the substrate S2 has been completed. In some embodiments, the instruction to move the stage 130′ may be in response to information regarding the completion of the processing of the substrate S1 and the completion of the alignment of the substrate S2. In other words, the stage 130′ may not be instructed to move until both the processing of the substrate S1 is complete and the substrate S2 is aligned.

At stage 408, the substrate S2 may be processed while at the processing position 125 for a second processing time. The substrate S2 may be processed, for example, as described above. The second processing time may be the same as or different from the first processing time. During the second processing time, any combination of the following may occur: a transfer robot may unload the substrate S1 from the stage 130; the transfer robot may load and/or position a third substrate S3 on the stage 130; and the substrate S3 may be aligned on the stage 130. After the stage 408, the processing system 100 may be as depicted in FIG. 5C.

At stage 410, the stage 130 may move to the processing position 125 for processing while the stage 130′ may move to the loading position 127′. The movement may be instructed by, for example, the controller 150. The instruction to move the stage 130 may be in response to information provided to the controller 150 that the processing of the substrate S2 has been completed or a determination made by the controller 150 that the processing of the substrate S2 has been completed. The controller 150 may determine that processing has been completed based on the expiry of a predetermined amount of time or otherwise. The instruction to move the stage 130 may be in response to information provided to the controller 150 that the alignment of the substrate S3 has been completed or a determination made by the controller 150 that the alignment of the substrate S3 has been completed. In some embodiments, the instruction to move the stage 130 may be in response to information regarding the completion of the processing of the substrate S2 and the completion of the alignment of the substrate S2. In other words, the stage 130 may not be instructed to move until both the processing of the substrate S2 is complete and the substrate S3 is aligned.

The instruction to move the stage 130′ may be in response to information provided to the controller 150 that the processing of the substrate S2 has been completed or a determination made by the controller 150 that the processing of the substrate S2 has been completed. The instruction to move the stage 130′ may be in response to information provided to the controller 150 that the alignment of the substrate S3 has been completed or a determination made by the controller 150 that the alignment of the substrate S3 has been completed. In some embodiments, the instruction to move the stage 130′ may be in response to information regarding the completion of the processing of the substrate S2 and the completion of the alignment of the substrate S3. In other words, the stage 130′ may not be instructed to move until both the processing of the substrate S1 is complete and the substrate S2 is aligned.

At stage 412, the substrate S3 may be processed at the processing position 125 for a third processing time. The third processing time may be the same as or different from either or both of the first and/or second processing time. During the third processing time, any combination of the following may occur: the transfer robot may unload the substrate S2 from the stage 130′; the transfer robot may load and/or position a fourth substrate S4 on the stage 130′; the substrate S4 may be aligned on the stage 130′. After the stage 412, the processing system 100 may be as depicted in FIG. 5D. At optional stage 414, the stages 406, 408, 410, and 412 may be repeated any number of times.

The previously described embodiments have many advantages, including the following. For example, the embodiments disclosed herein may reduce or eliminate the idle time of a processing apparatus of a processing system. By decreasing or eliminating idle time, embodiments disclosed herein allow for increased processing throughput. The increased throughput may allow for reducing the price of display devices for consumers and/or increased profits for device manufacturers. Additionally, the embodiments disclosed herein may allow for new fabrication process flows. The aforementioned advantages are illustrative and not limiting. It is not necessary for all embodiments to have all the advantages.

While the foregoing is directed to embodiments of the present disclosure, other and further embodiments of the disclosure may be devised without departing from the basic scope thereof, and the scope thereof is determined by the claims that follow.

What is claimed is:

1. A processing system comprising:
at least one processing apparatus, wherein the at least one processing apparatus is configured to change the chemical or mechanical properties of at least one layer of a substrate;
at least two stages, wherein each stage is independently moveable between a processing position and a respective loading position, wherein at least one processing position is located between at least two loading positions, wherein each stage is configured to align a substrate positioned thereon, and wherein the number of independently moveable stages is greater than the number of processing apparatuses; and
a controller,
wherein the controller is configured to instruct the movement of a stage positioned at a processing position in response to the completion of a substrate processing procedure performed by the at least one processing apparatus, and
wherein the controller is configured to instruct the movement of a stage positioned at a loading position in response to the completion of a substrate alignment procedure performed at the respective loading position.

2. The processing system of claim 1, wherein each stage is associated with a single loading position.

3. The processing system of claim 2, wherein the at least one processing apparatus is a pattern generator configured to expose a photoresist in a photolithography process.

4. The processing system of claim 3, wherein the pattern generator is a maskless lithography pattern generator.

5. The processing system of claim 3, further comprising at least one transfer robot configured to position a substrate on at least one of the at least two stages.

6. The processing system of claim 3, wherein at least one stage includes one or more lift pins.

7. The processing system of claim 3, further comprising a plurality of observation cameras disposed adjacent each stage, wherein each observation camera is configured to:
view alignment marks disposed on the substrate being processed; or
view alignment marks disposed on the stage, wherein data collected from the observation cameras are fed back to the controller that coordinates movement of the stage to align the substrate; and wherein each observation camera detects the distortion of the substrate such that the coordinates of the substrate and stage is a non-linear relationship.

8. The processing system of claim 3, wherein the processing system comprises two stages and one processing apparatus.

9. The processing system of claim 1, further comprising a plurality of observation cameras disposed adjacent each stage, wherein each observation camera is configured to:
view alignment marks disposed on the substrate being processed; or view alignment marks disposed on the stage, wherein data collected from the observation cameras are fed back to the controller that coordinates movement of the stage to align the substrate; and wherein each observation camera detects the distortion of the substrate such that the coordinates of the substrate and stage is a non-linear relationship.

10. The processing system of claim 3, wherein the stages are configured to move along a track, and wherein the processing position is positioned substantially at the center of the track.

11. The processing system of claim 3, wherein the at least two stages are configured to move along at least one track.

12. The processing system of claim 3, wherein the processing system is a linear processing system.

13. The processing system of claim 3, wherein the processing system comprises an air bearing system.

14. A processing system comprising:
a single processing apparatus, wherein the processing apparatus is a pattern generator configured to expose a photoresist in a maskless photolithography process;
at least two stages, wherein each stage is independently moveable between a processing position and a respective loading position, wherein at least one processing position is located between at least two loading positions, wherein each stage is associated with a single loading position, wherein each stage is configured to align a substrate positioned thereon, and wherein at least one stage includes one or more lift pins;
at least one transfer robot configured to position a substrate on at least one of the at least two stages; and
a controller,
wherein the controller is configured to instruct the movement of a stage positioned at a processing position in response to the completion of a substrate processing procedure performed by the at least one processing apparatus, and
wherein the controller is configured to instruct the movement of a stage positioned at a loading position in response to the completion of a substrate alignment procedure performed at the respective loading position; and
wherein the processing system is a linear processing system.

15. A method of processing two or more substrates, the method comprising:
a) processing a first substrate positioned on a first stage for a first processing time while the first substrate is located at a processing position;
b) aligning, during the first processing time, a second substrate positioned on a second stage while the second stage is located at a second loading position;
c) moving, after the first processing time, the second stage to the processing position while moving the first stage toward a first loading position.

16. The method of claim 15, further comprising:
d) processing, for a second processing time, the second substrate while the second substrate is positioned on the second stage and located at the processing position;
e) performing, at the first loading position and during the second processing time, at least one of 1) unloading the first substrate from the first stage, 2) loading a third substrate on the first stage, or 3) aligning the third substrate on the first stage.

17. The method of claim 16, wherein the processing of the first substrate and the processing of the second substrate comprises exposing a photoresist on the respective substrate in a photolithography process.

18. The method of claim 17, wherein the photolithography process is a maskless photolithography process.

19. The method of claim 15, wherein e) comprises performing each of 1) unloading the first substrate from the first stage, 2) loading a third substrate on the first stage, and 3) aligning the third substrate on the first stage.

20. A substrate processed according to claim 15.
